(19) United States
(12) Patent Application Publication
(10) Pub. No.: US 2018/0204967 A1
(43) Pub. Date: Jul. 19, 2018

(54) Segmented Solar Module

(71) Applicants: David R. Hall, Provo, UT (US); Christopher Jones, Spanish Fork, UT (US); Austin Carlson, Provo, UT (US); Seth Myer, Eagle Mountain, UT (US)

(72) Inventors: David R. Hall, Provo, UT (US); Christopher Jones, Spanish Fork, UT (US); Austin Carlson, Provo, UT (US); Seth Myer, Eagle Mountain, UT (US)

(21) Appl. No.: 15/408,872

(22) Filed: Jan. 18, 2017

(51) Int. Cl. H01L 31/05; H01L 31/048; H01L 31/02; H01L 31/044; H02S 20/30; H02S 40/38; H02J 7/35; H02J 1/10; H02J 3/38; E06B 9/386; E06B 9/30

(52) U.S. Cl. CPC H01L 31/0504; H01L 31/048; H01L 31/02013; H01L 31/02021; H01L 31/044; H02S 20/30; E06B 2009/2476; H02J 7/355; H02J 1/102; H02J 3/385; E06B 9/386; E06B 9/30; H02J 2001/106; H02S 40/38

(57) ABSTRACT

A segmented solar module is disclosed. One or more Photovoltaic (PV) submodules are connected together with embedded parallel wiring that facilitates the sharing of power from a plurality of PV submodules to power one or more electrical devices. Each one of the two or more first submodules cover a surface area more than twice the size of the surface area covered by a second submodule. This allows the second submodule to be isolated from the first submodules to accommodate shading of the second submodule. Control electronics within each individual PV submodule allows the isolation of PV modules that are shaded or otherwise not productive. No external connecting wiring, or devices are required to make the system functional. All wiring, connectors and electronics are integral and embedded within each individual PV module. The PV modules have adhesive on the back to allow them to be installed without additional mounting hardware. All submodules, wiring and electronic components are completely encapsulated together in one solar module.

### BACKGROUND

### Field of the Invention

This invention relates to modular photovoltaic systems.

### Background of the Invention

Solar power systems are typically mounted in a location facing the sun in order to maximize the exposure to solar energy. However, there can be obstructions to the direct sunlight needed to power the solar panels. Clouds, trees, and architectural features or building elements can cause shading. Even partial shading of the solar panel can dramatically reduce the power output since the electron flow inside the panel is in series. Shading of only one section or portion of the solar panel will block the flow for the entire panel or group of panels.

Traditional solar power systems normally include multiple solar panels that are connected to each other by either parallel or series wiring (or a combination of both).

Prior to the introduction of microinverters, most if not all solar power systems were wired in series, having several “strings” of panels (a group of many panels, circuited in series), with each string feeding into a large power inverter that converted the DC power to AC power. The main disadvantage of this design is the fact that if there is shading on even one single panel within the string, it affects the current flow of that entire string (because they are wired in series), and reduces the total string power output to the lowest electrical current flow restriction created by the shading of that one panel. By wiring the system in a parallel configuration, this problem can be solved.

Many approaches to making solar power systems “modular” or easily expandable have been proposed in order to simplify the installation of the system. A large portion of these consist of unique mounting systems that attach to the roof, and connection techniques that allow multiple solar modules or panels to be connected together. The attachment system usually has some kind of rack or structure that first attaches to the roof or building structure, then the solar panels are mechanically attached to that support structure.

Some of the proposed modular systems incorporate parallel wiring along with microinverters that parallel with each other in order to interface with an AC system connected to the utility. However, they convert it to AC before performing the paralleling function. The parallel wiring is not typically incorporated within each individual module. The parallel wiring that connects multiple solar modules is normally run separate from the module in a protected cabling, raceway or electrical bus structure. Also, the electronics that perform the paralleling function are typically in a separate enclosure such as a microinverter, device or component with requisite wires connecting it to the rest of the system. The interconnecting wiring is cut to length for the specific application or configuration.

The described solar power systems are typically for large solar panels rather than smaller modules, and do not integrate the parallel wiring into the individual modules. Smaller surface areas (for example architectural features such as long narrow linear building fascias, columns or window frames) cannot accommodate these larger format solar panels.

In summary, the key advantages posited for the segmented solar module include a module that:

Is segmented into several submodules that each contribute to the total power output of the solar module, wherein shaded submodules are automatically isolated from the productive submodules allowing the module to still produce power.

incorporates the parallel wiring into each individual module,

is in a smaller format that can fit on a variety of surfaces, even ones that are narrow or small,

has embedded wiring which allows the modules to be arranged in any configuration.

incorporates the control electronics for the paralleling function inside each module,

has a higher resolution for isolating sections of the system that are shaded by incorporating a group of smaller modules rather than one large module,

can adjust to fit both smaller surface areas and be extended to longer areas by adding more modules, and

can be directly attached to a smooth surface area without any other separate support structure.

### SUMMARY

This invention has been developed in response to the present state of the art and, in particular, in response to the problems and needs in the art that have not yet been fully solved by currently available systems and methods. Features and advantages of different embodiments of the invention will become more fully apparent from the following description and appended claims, or may be learned by practice of the invention as set forth hereinafter.

Consistent with the foregoing, a segmented solar module is disclosed which simplifies the installation of, improves the shade tolerance and power production of solar power systems.

One or more Photovoltaic (PV) submodules are connected together with embedded parallel wiring that facilitates the sharing of power from a plurality of PV submodules to power one or more electrical devices. Each one of the two or more first submodules cover a surface area more than twice the size of the surface area covered by a second submodule. This allows the second submodule to be isolated from the first submodules to accommodate shading of the second submodule. Control electronics within each individual PV submodule allows the isolation of PV modules that are shaded or otherwise not productive. No external connecting wiring, or devices are required to make the system functional. All wiring, connectors and electronics are integral and embedded within each individual PV module. The PV modules have adhesive on the back to allow them to be installed without additional mounting hardware. All submodules, wiring and electronic components are completely encapsulated together in one segmented solar module.

By providing a segmented approach, submodules that are being shaded can be isolated within the module from productive submodules. In this design, each submodule that receives enough light will contribute to the total power generated by the group. Shaded submodules will not interrupt the current generated by the productive submodules since they are electrically isolated when not producing.

In an embodiment wherein the segmented solar module is mounted inside a building on the headrail of a window frame, the center section of the solar module will be shaded from a center vertical frame member of the window frame during certain times of the day. In this embodiment of the solar segmented module, the second submodule is in the center shaded section, with the two first submodules in the sunlight on either side of the second submodule, the second submodule being isolated from the first two submodules. During times of the day when the second submodule is not being shaded, it can contribute to the overall power production of the parallel wired system of multiple submodules. Typically, the area being shaded by the center vertical frame member is much smaller than the glass area of the window. The glass area is more than half of the area being shaded thus requiring less than half of the surface area covered by the second submodule.

Each solar module produces the same voltage, and the current they produce is additive to the current flowing through the system produced by a plurality of solar modules in parallel.

This design also allows the system to be expandable in the future, if and when additional power is required. As additional solar modules are added, the voltage remains the same and the current increases which provides the increased power capacity.

Another advantage of this system is the ability to adjust the overall size of the system to fit the dimensions of the available surface area. With the segmented approach, the number of solar modules can be adjusted to fit the length required.

It will be readily understood that the components of the present invention, as generally described and illustrated in the Figures herein, may be arranged and designed in a wide variety of different configurations. Thus, the following more detailed description of the embodiments of the invention is not intended to limit the scope of the invention, as claimed, but is merely representative of certain examples of presently contemplated embodiments in accordance with the invention. The presently described embodiments will be best understood by reference to the claims and drawings.

Certain embodiments of the invented segmented solar module include: a photovoltaic (PV) module producing a current including two or more first submodules, wherein each first submodule comprise one or more photovoltaic (PV) cells electrically connected to provide a voltage V1, the PV module further including one or more second submodules, wherein each second submodule comprises one or more photovoltaic (PV) cells electrically connected to provide a voltage V2 that is equal to the first submodule voltage V1, wherein V1=V2, and wherein one second submodule covers a surface area of less than half of the surface area covered by one first submodule. The PV module further includes parallel wiring connecting the first submodules to the second submodules; along with controllers that have electronics allowing the current to bypass one or more submodules that are not producing any current; and the PV module further comprising an encapsulation material enclosing the two or more first submodules, the one or more second submodules, the parallel wiring, and the controllers.

In one embodiment, the PV module further comprises a plurality of contacts connected to the embedded parallel wiring wherein the contacts couple one or more PV modules together. These contacts are partially embedded in the surface of the PV module with a top surface of the contacts being flush with an outer surface of the PV module.

In another embodiment, the number of PV cells in the first PV module are equal to the number of PV cells in the second PV module; the PV cells of the first PV module being spread apart from each other having space in between each of the PV cells thus covering a larger surface area; and the PV cells in the second PV module being close to each other with minimal spacing having a tighter spacing thus covering a smaller surface area.

In a certain embodiment, the PV module further including each of two or more groups of PV cells in the first submodule connected in series, each series string equaling the voltage V1, and all strings of the one or more groups being connected in parallel; and one group of PV cells in the second submodule connected in series, the one group series string equaling the voltage V1.

In one embodiment, the controller comprises bypass diodes, and in another embodiment the controller comprises electronics that modulate the power output of the one or more submodules during periods of shading or lower power production to provide a power contribution to a total power output of the PV modules. In yet another embodiment, the controller comprises Maximum Power Point Tracking (MPPT) electronics.

In certain embodiments, the PV module is connecting and providing power to one or more electrical components. In some embodiments, the electrical components comprise a system for charging energy storage devices or components.

In another embodiment, one or more PV modules are attached to a window covering system. In certain embodiments, one or more PV modules are integrated into window covering components at a time of manufacture of a window covering system. In one embodiment, one or more PV modules are mounted to a front side of blind slats within the window covering system. In another embodiment, one or more PV modules are mounted to both a front and back side of blind slats within the window covering system.

In one embodiment, the connecting and providing power to one or more electrical components comprises flexible electrical wiring that clips onto a support or control string between blind slats. In an embodiment, the PV module is provided with a mounting system connecting to a headrail of a window covering system that suspends the PV module at a lower level where it will receive more exposure to the sun. In another embodiment, the mounting system is adjustable and the PV module slides either up towards a headrail or down lower where it will receive more exposure to the sun, locking in to a specific position after being properly adjusted.

In certain embodiments, the controller electronics are incorporated into the PV module's internal circuiting. In other embodiments, each PV module includes interconnecting parallel wiring embedded within the PV module, the interconnecting parallel wiring linking two or more PV modules, providing a pathway for the current of two or more PV modules.

In another embodiment, the PV module also includes control wiring embedded within the PV module, the control wiring interconnecting two PV modules providing a pathway for the control signals of two or more PV modules. In an embodiment, the interconnecting parallel wiring provides a pathway for both power and control functions.

In one embodiment, each PV module includes peel and stick adhesive backing to allow the PV module to be adhered to a surface.

### BRIEF DESCRIPTION OF THE DRAWINGS

In order that the advantages of the invention will be readily understood, a more particular description of the invention briefly described above will be rendered by reference to specific embodiments illustrated in the appended drawings. Understanding that these drawings depict only typical embodiments of the invention and are not therefore to be considered limiting of its scope, the invention will be described and explained with additional specificity and detail through use of the accompanying drawings, in which:

FIG. 1A is an illustration of a PV module comprising three submodules according to one example embodiment.

FIG. 1B is an illustration of a PV module comprising five submodules according to one example embodiment.

FIG. 2 is a cross section of a PV module showing the internal components according to one example embodiment.

FIG. 3 is a top view of a PV module showing the internal components according to one example embodiment.

FIG. 4 is a top view of a PV module showing the internal components according to another example embodiment.

FIG. 5A illustrates a PV module mounted to the headrail of window blinds according to one example embodiment.

FIG. 5B illustrates an example of a PV module mounted inside a building near the top of a window frame according to one example embodiment.

FIG. 6A illustrates an example of a PV module mounted to the headrail of a longer set of window blinds according to one example embodiment.

FIG. 6B illustrates an example of a PV module mounted inside a building near the top of a longer window frame according to one example embodiment.

FIG. 7 illustrates an example of PV modules mounted to blind slats according to one example embodiment.

FIG. 8 illustrates an example of how the PV modules can be mounted to both sides of a blind slat according to one example embodiment.

FIG. 9 shows electrical devices inside a headrail, and PV modules mounted on a blind slat according to one example embodiment.

FIG. 10 is a perspective view of a set of horizontal blinds with a PV module shown on the window facing side of a headrail according to one example embodiment.

FIG. 11A is a perspective view of a set of horizontal blinds showing an adjustable mounting system according to one example embodiment.

FIG. 11B is a perspective view of a set of horizontal blinds showing an adjustable mounting system according to another example embodiment.

FIG. 12A is a side view of an adjustable mounting system showing a PV module in a high position near the headrail according to one example embodiment.

FIG. 12B is a side view of an adjustable mounting system showing a PV module in a low position below the headrail according to one example embodiment.

FIG. 13 illustrates a PV module with an adhesive backing and protective backing material according to one example embodiment.

### DETAILED DESCRIPTION OF THE DRAWINGS

It will be readily understood that the components of the present invention, as generally described and illustrated in the Figures herein, could be arranged and designed in a wide variety of different configurations. Thus, the following more detailed description of the embodiments of the invention, as represented in the Figures, is not intended to limit the scope of the invention, as claimed, but is merely representative of certain examples of presently contemplated embodiments in accordance with the invention. The presently described embodiments will be best understood by reference to the drawings, wherein like parts are designated by like numerals throughout.

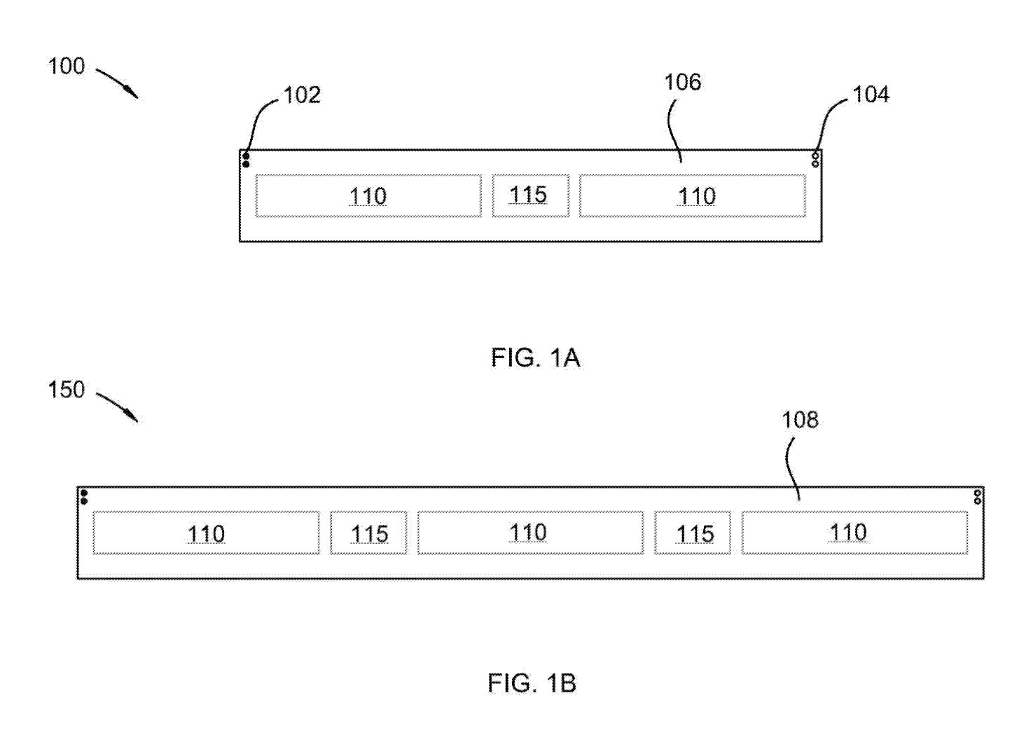

FIG. 1A is an illustration of one example of a PV module comprising three submodules. The drawing 100 shows a top view of the PV module 106 comprising a first submodule 110 covering a surface area at least twice the surface area as that covered by a second submodule 115. There is also an additional first submodule 110 shown on the opposite side of the PV module 106. The module connectors 102 on the top of the PV module are designed to connect to the module connectors 104 on the bottom of an adjacent PV module. Each PV module 106 is fully functional without any other PV modules connected to it. This configuration allows the center submodule 115 to be electrically isolated from the adjacent first submodules 110 during times periods of shading of submodule 115.

FIG. 1B is an illustration of an example of a PV module comprising five submodules. The drawing 150 shows a top view of the PV module 108 comprising several of the first submodules 110 along with two of the second submodules 115. The module connectors 102 on the top of the PV module are designed to connect to the module connectors 104 on the bottom of an adjacent PV module. Each PV module 108 is fully functional without any other PV modules connected to it. In this embodiment, there are multiple second submodules 115 that can be electrically isolated from productive first submodules 110.

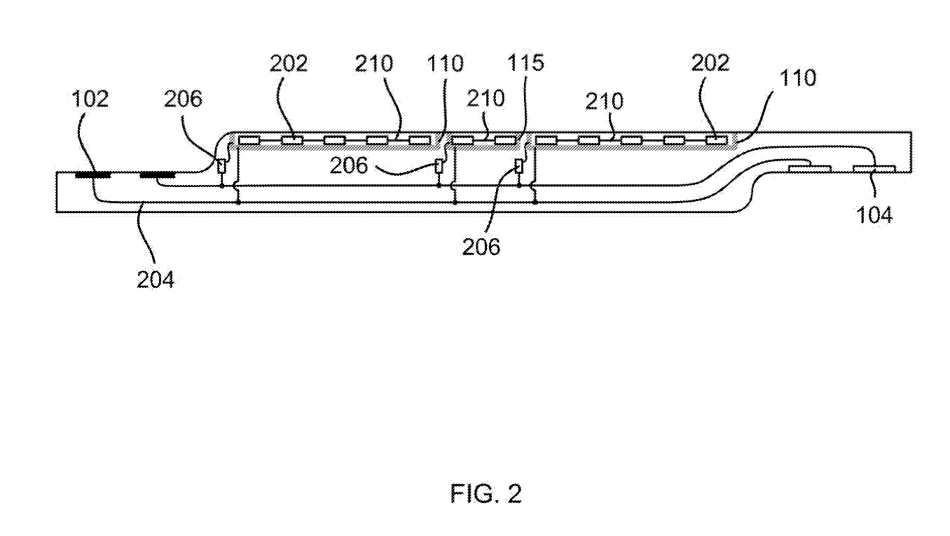

FIG. 2 is a cross section of a PV module showing the internal components. Photovoltaic cells 202 are arranged at the top of the PV module facing up and interconnected electrically. In this embodiment, first submodules 110 are each connected to a controller. Second submodule 115 is also connected to its own controller. Interconnecting wiring 210 electrically connects the photovoltaic cells 202 together. Module connectors 102 are mounted on the top of the PV module. Module connectors 104 are mounted on the bottom of the PV module. Embedded parallel wiring 204 connects to modular connectors 102 and module connectors 104, to photovoltaic cells 202 and to control electronics 206. The encapsulation material 208 completely encapsulates all of the components, integrating them into one complete encapsulated assembly. Contacts 102 and 104 are embedded into the encapsulation material as shown with only one exposed surface of the electrically conductive contact material

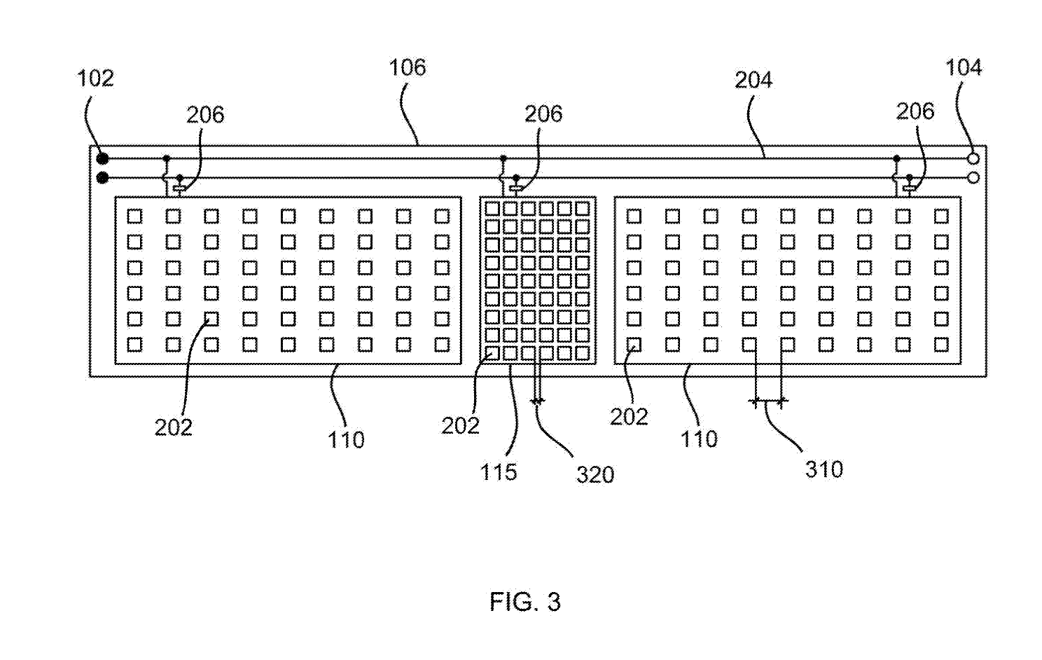

FIG. 3 is a top view of a PV module showing the internal components. Photovoltaic cells 202 are arranged at the top of the PV module 106 facing up and interconnected electrically. Contacts 102 are mounted on the top of the PV module. Contacts 104 are mounted on the bottom of the PV module. Embedded parallel wiring 204 connects to contacts 102 and contacts 104 and to the interconnected photovoltaic cells 202 and to control electronics 206. The photovoltaic cells 202 in submodule 110 are spaced apart as shown in spacing dimension 310. The total number of photovoltaic cells 202 in submodule 110 are equal to the total number of photovoltaic cells 202 in submodule 115. The spacing of the photovoltaic cells 202 in submodule 115 are much closer together as shown in spacing dimension 320. All of the photovoltaic cells 202 within each of the submodules are circuited in series. Since the number of photovoltaic cells 202 within both first submodules 110 and second submodule 115 are equal in number, the voltages of each of the three submodules are equal.

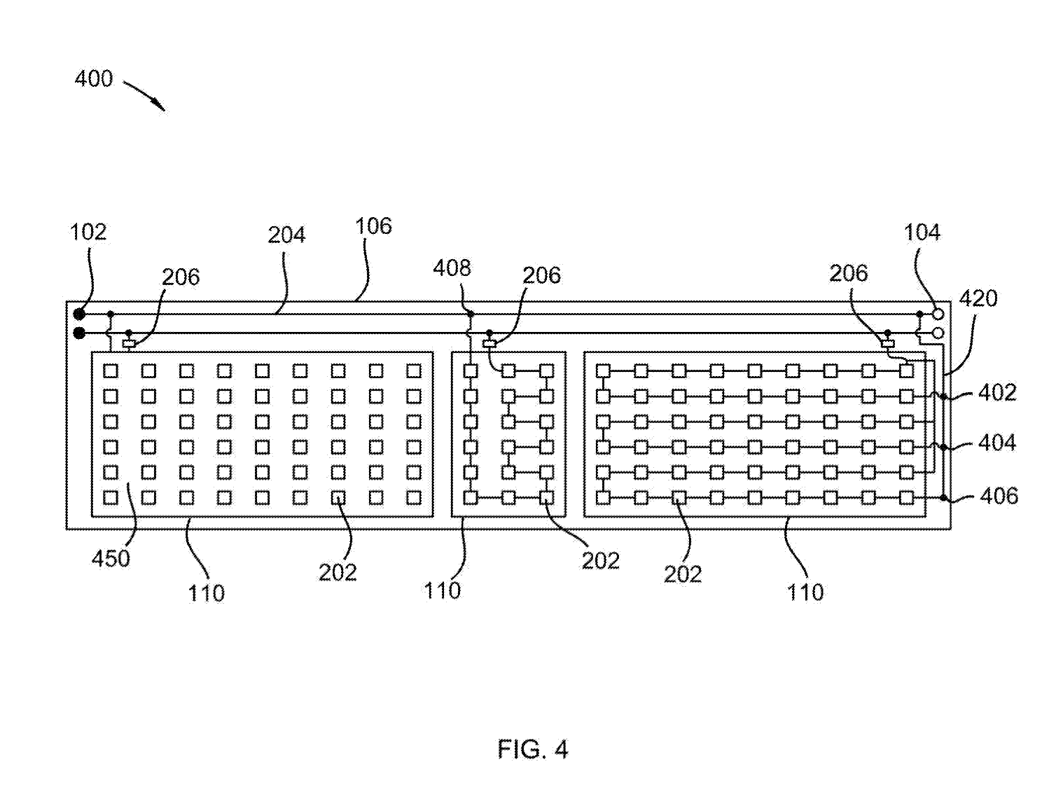

FIG. 4 is a top view of a PV module showing the internal components. Photovoltaic cells 202 are arranged on the top of the PV module 106 facing up and interconnected electrically. Module connectors 102 are mounted on the top of the PV module. Module connectors 104 are mounted on the bottom of the PV module. Embedded parallel wiring 204 connects to modular connectors 102 and module connectors 104 and to the interconnected photovoltaic cells 202 and to control electronics 206. In this embodiment, the photovoltaic cells 202 within the second submodule 115 are all circuited in series 408. In this example, each photovoltaic cell 202 has a voltage of 0.6 volts. There are 18 PV cells which total 10.8 volts when connected together in series.

Drawing 400 shows the PV module 106 comprising three submodules. Submodules 110 each have three series circuits identified as 402, 404 and 406. Circuit 402 comprises 18 PV cells at 0.6 volts each which totals 10.8 volts for the series circuit. Circuits 404 and 406 each total 10.8 volts. The three circuits 402, 404 and 406 are connected in parallel 420 as shown. The total connected voltage of first submodule 110 is 10.8 volts which is also equal to second submodule 115 voltage of 10.8 volts. The PV cells 202 in the area 450 are also circuited with three series circuits, each at 10.8 volts.

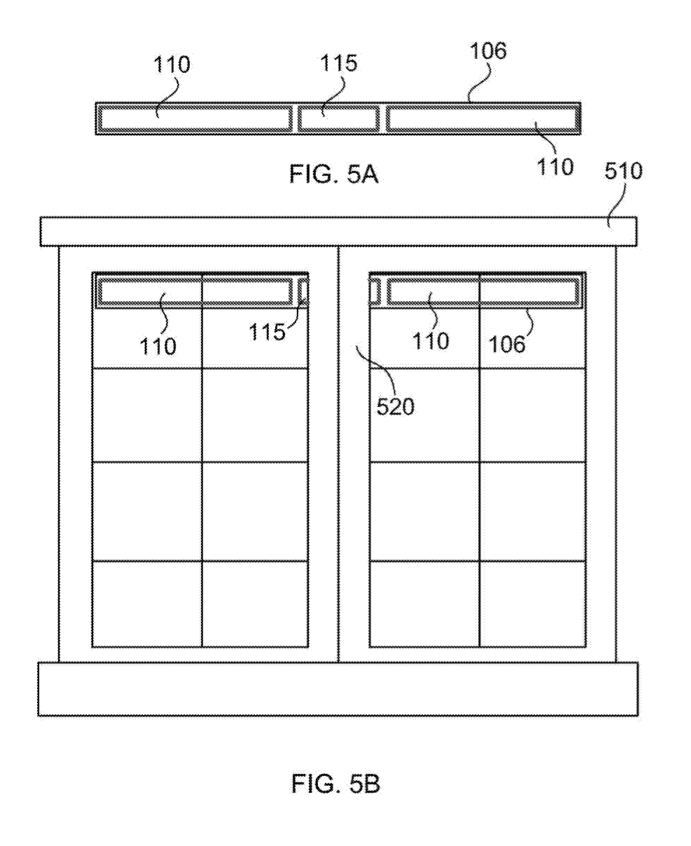

FIG. 5A illustrates an example of PV module 106 mounted to the headrail of window blinds. First submodules 110 and second submodule 115 are shown within PV module 106 mounted to the window facing side of the headrail.

FIG. 5B illustrates an example of PV module 106 mounted inside a building near the top of window frame 510. Submodules 110 on either side of the center frame 520 are unobstructed from any shading. Submodule 115 is behind center frame 520 which shades submodule 115 during certain times of the day.

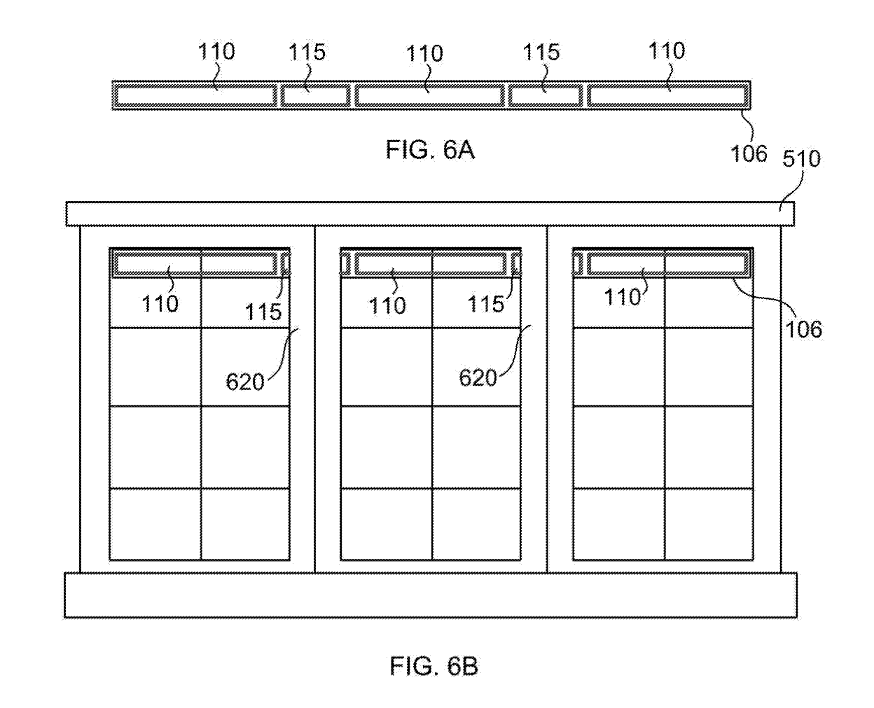

FIG. 6A illustrates an example of PV module 106 mounted to the headrail of window blinds. In this embodiment, there are three first submodules 110 and two second submodules 115. PV module 106 mounted to the window facing side of the headrail.

FIG. 6B illustrates an example of PV module 106 mounted inside a building near the top of window frame 510. Each of the three submodules 110 are unobstructed from any shading. The two submodules 115 are each behind window frame member 620 which shades submodules 115 during certain times of the day.

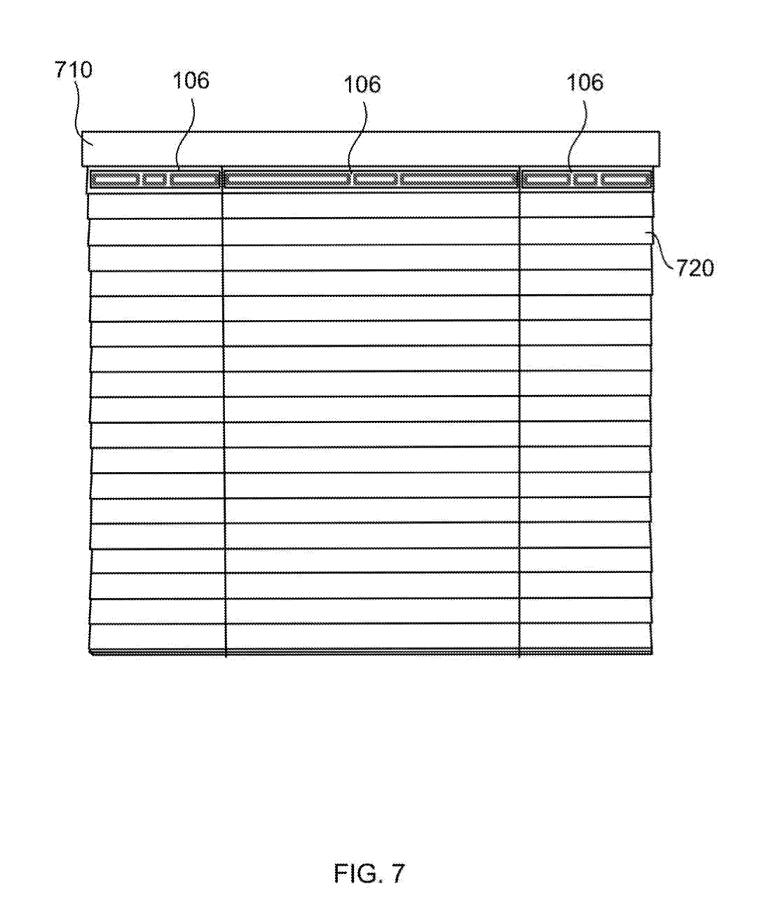

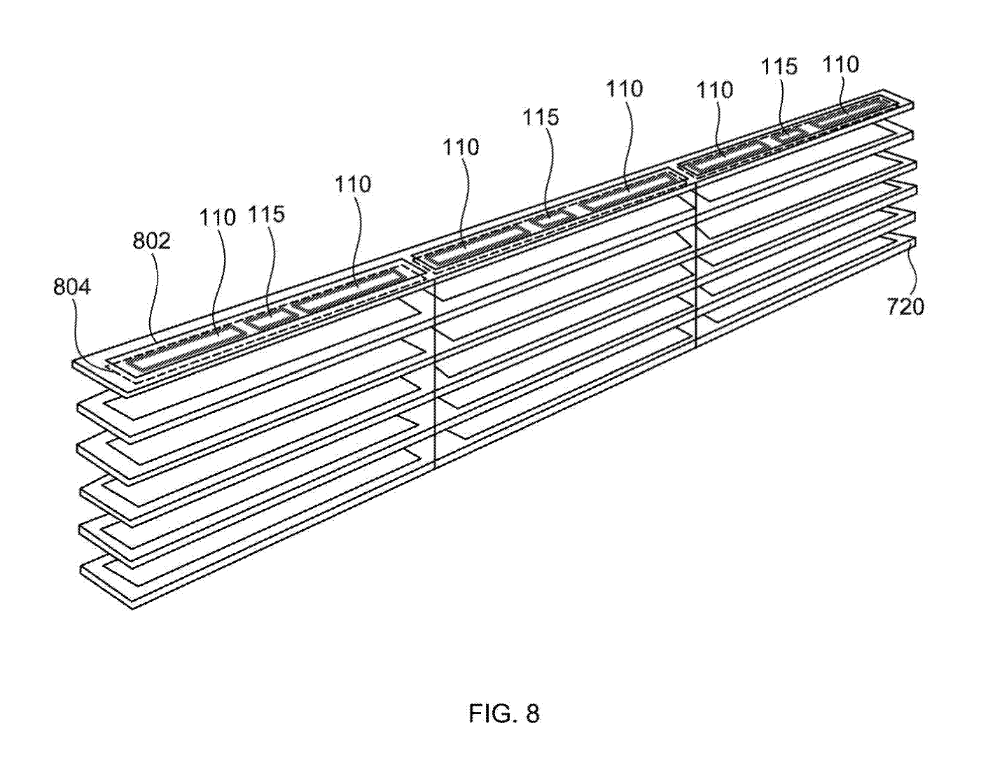

FIG. 7 illustrates an example of PV modules 106 mounted to blind slats 720. Headrail 710 is at the top of the blinds.

FIG. 8 illustrates an example of how the PV modules can be mounted to both sides of a blind slat. A continuous row of interconnected PV modules 802 is mounted on the top of the blind slat 720. A continuous row of interconnected PV modules 804 is mounted on the bottom of the blind slat 720.

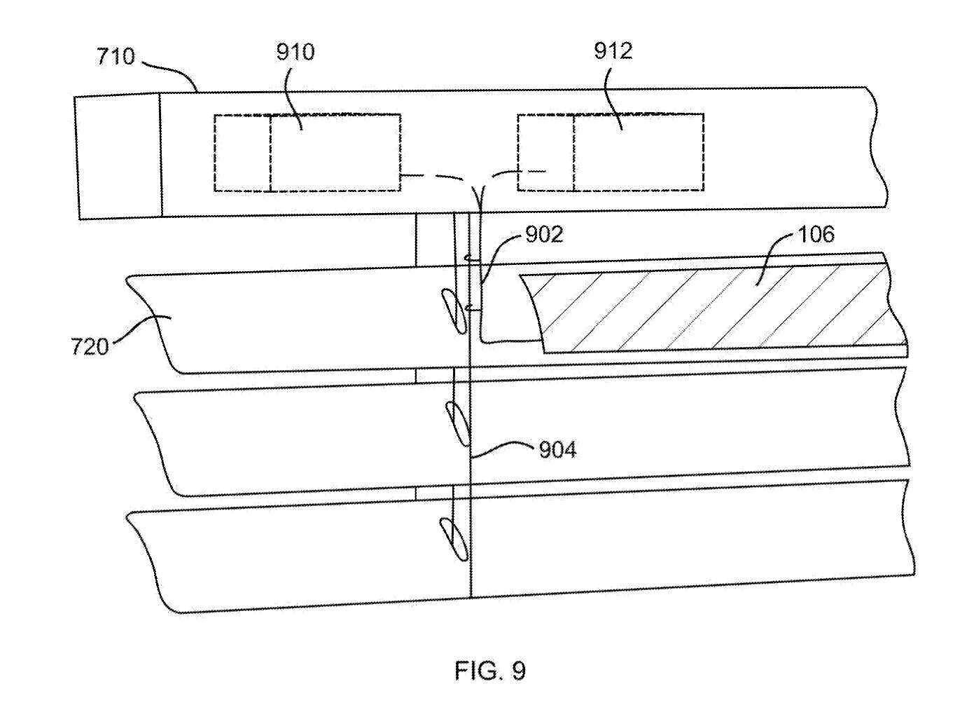

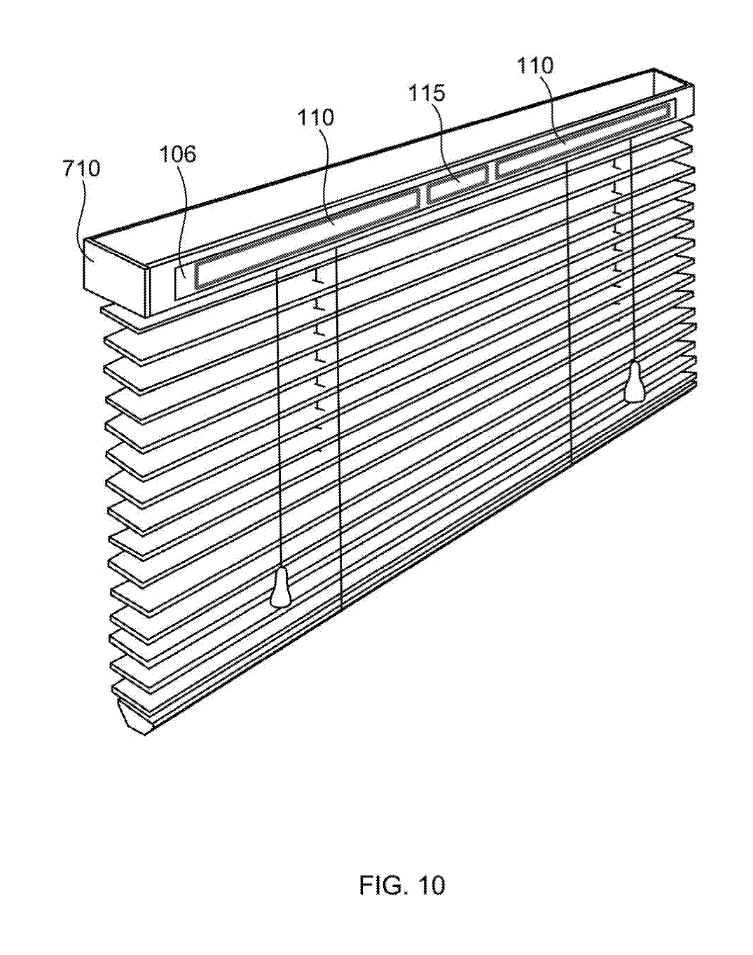

FIG. 9 shows a continuous row of interconnected PV modules 106 mounted on the blind slat 720. Interconnecting electrical wiring 902 extends from the PV modules 106 up to the electrical components 912 and energy storage devices 910, which are mounted inside the headrail 710. The interconnecting wiring 902 is flexible and is clipped onto the blind slat support string 904.

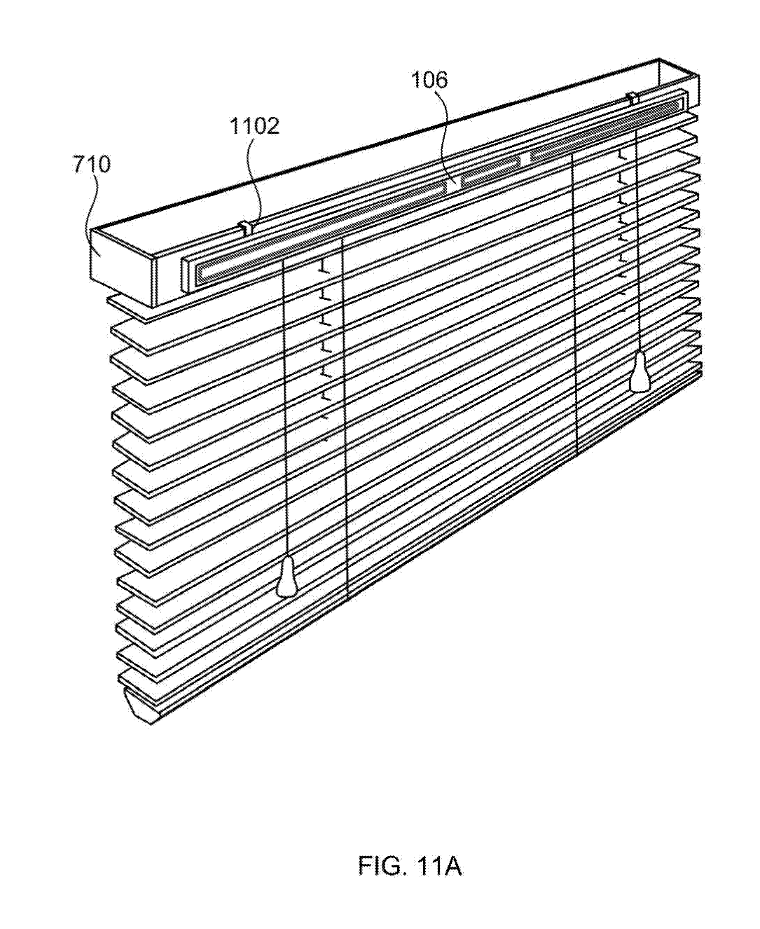

FIG. 10 is a perspective view of a set of horizontal blinds with PV module 106 shown on the window facing side of the headrail 710. First submodules 110 and submodule 115 are also shown facing the window and being exposed to sunlight entering through the window.

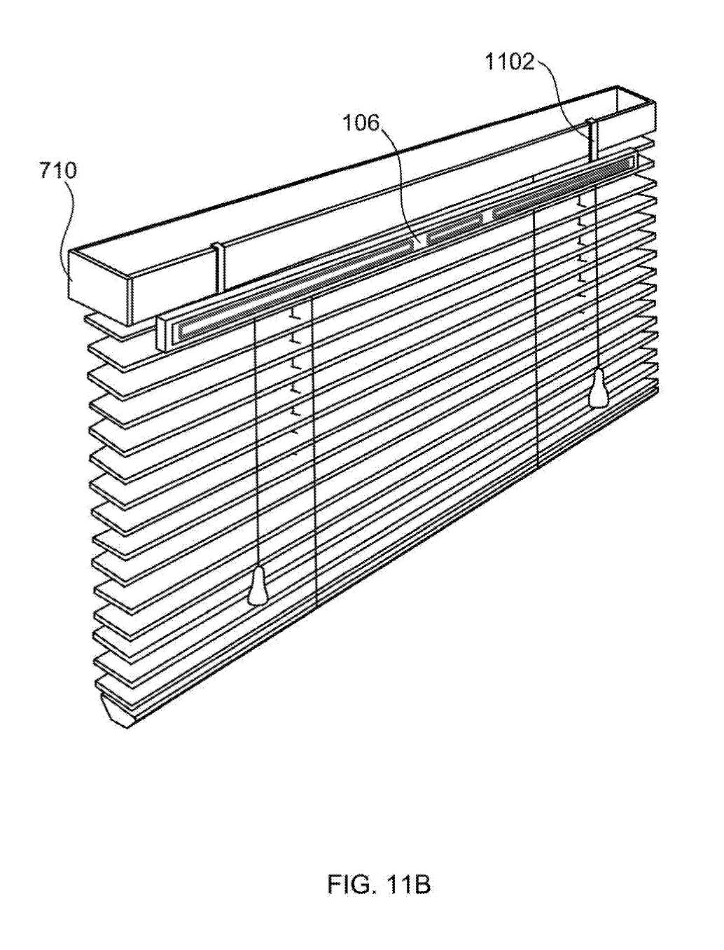

FIG. 11A is a perspective view of a set of horizontal blinds showing the adjustable mounting system 1102 with PV module 106 mounted on the headrail 710 of the blinds.

FIG. 11B is a perspective view of a set of horizontal blinds showing the adjustable mounting system 1102 with PV module 106 in a lower position below the headrail 710.

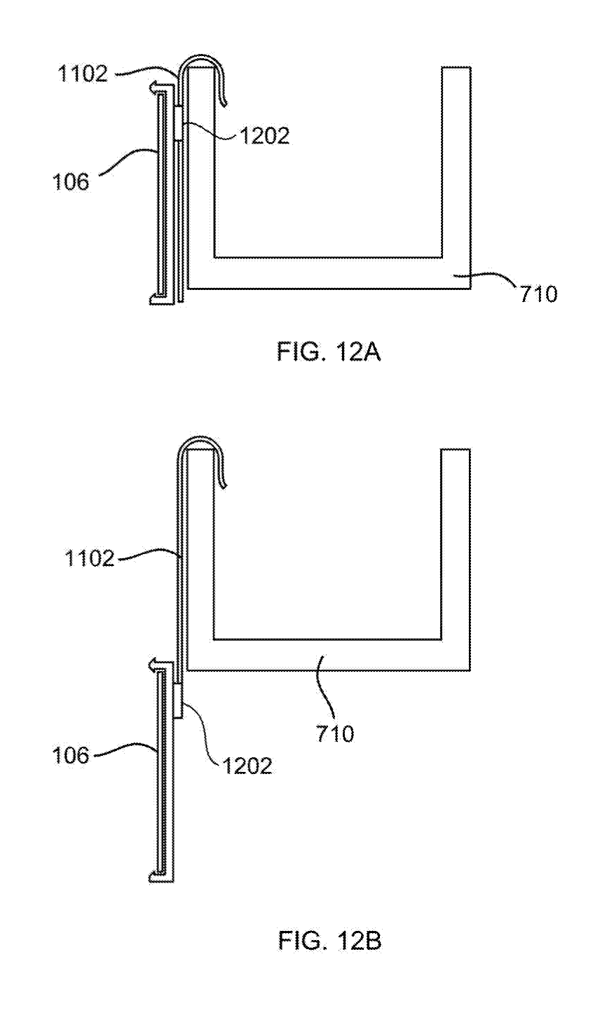

FIG. 12A is a side view of the adjustable mounting system 1102 showing PV module 106 in the high position near the headrail 710. Locking mechanism 1202 retains the track in this high position.

FIG. 12B is a side view of the adjustable mounting system 1102 showing PV module 106 in the low position below the headrail 710. Locking mechanism 1202 retains the track in the low position.

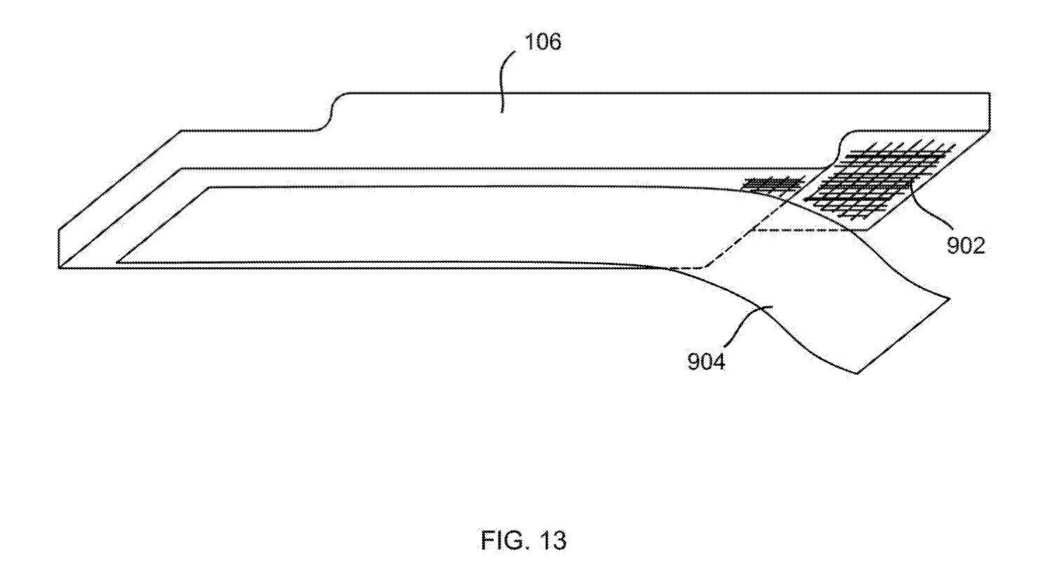

FIG. 13 illustrates PV module 106 with an adhesive backing 902 and protective backing material 904. The protective backing material 904 is removed when the PV module 106 is installed onto a surface to enable the PV module to be adhesively attached to the surface.

1. A photovoltaic (PV) module producing a current comprising:
two or more first submodules, wherein each first submodule comprises:
one or more photovoltaic (PV) cells electrically connected to provide a voltage V1;
one or more second submodules, wherein each second submodule comprises:
one or more photovoltaic (PV) cells electrically connected to provide a voltage V2 that is equal to the first submodule voltage V1, wherein V1=V2, and wherein one second submodule covers a surface area of less than half of the surface area covered by one first submodule.
embedded parallel wiring connecting the first submodules to the second submodules and to one or more controllers;
the controllers comprising electronics that allows the current to bypass one or more submodules that are not producing any current; and
the PV module further comprising an encapsulation material enclosing the two or more first submodules, the one or more second submodules, the embedded parallel wiring, and the controllers.

2. The PV module of claim 1, wherein the PV module further comprises a plurality of contacts connected to the embedded parallel wiring wherein the contacts electrically connect one or more PV modules together; the contacts being partially embedded in the surface of the PV module with a top surface of the contacts being flush with an outer surface of the PV module, the contacts comprising electrically conductive materials.

3. The PV module of claim 1, wherein the number of PV cells in the first PV module are equal to the number of PV cells in the second PV module;
the PV cells of the first PV module being spread apart from each other having space in between each of the PV cells thus covering a larger surface area; and
the PV cells in the second PV module being close to each other with minimal spacing having a tighter spacing thus covering a smaller surface area.

4. The PV module of claim 1, further comprising:
each of two or more groups of PV cells in the first submodule connected in series, each series string equaling the voltage V1, and all strings of the one or more groups being connected in parallel; and
one group of PV cells in the second submodule connected in series, the one group series string equaling the voltage V1.

5. The PV module of claim 1, wherein the controllers comprise bypass diodes.

6. The PV module of claim 1, wherein the controllers comprise electronics that modulate the power output of the one or more submodules during periods of shading or lower power production to provide a power contribution to a total power output of the PV modules.

7. The PV module of claim 1, wherein the controllers comprise Maximum Power Point Tracking (MPPT) electronics.

8. The PV module of claim 1, wherein the PV module is connecting and providing power to one or more electrical components.

9. The PV module of claim 8, wherein the connecting and providing power to one or more electrical components comprises flexible electrical wiring that clips onto a support or control string between blind slats.

10. The PV module of claim 8, wherein the one or more electrical components comprise a system for charging energy storage devices or components.

11. The PV module of claim 1, wherein one or more PV modules are attached to a window covering system.

12. The PV module of claim 11, wherein one or more PV modules are integrated into window covering components at a time of manufacture of a window covering system.

13. The PV module of claim 11, wherein one or more PV modules are mounted to a front side of blind slats within the window covering system.

14. The PV module of claim 11, wherein one or more PV modules are mounted to both a front and back side of blind slats within the window covering system.

15. The PV module of claim 11, wherein the PV module is provided with a mounting system connecting to a headrail of a window covering system that suspends the PV module at a lower level where it will receive more exposure to the sun.

16. The PV module of claim 15, wherein the mounting system is adjustable and the PV module slides either up towards a headrail or down lower where it will receive more exposure to the sun, locking in to a specific position after being properly adjusted.

17. The PV module of claim 1, further comprising interconnecting parallel wiring embedded within the PV module, the interconnecting parallel wiring linking two or more PV modules, providing a pathway for the current of two or more PV modules.

18. The PV module of claim 1, further comprising control wiring embedded within the PV module, the control wiring interconnecting two PV modules providing a pathway for the control signals of two or more PV modules.

19. The PV module of claim 17, wherein the interconnecting parallel wiring provides a pathway for both power and control functions.

20. The PV module of claim 1, further comprising an adhesive backing on a back surface of the PV module, covered by a protective backing material to allow the PV module to be adhered to a surface when the protective backing material has been removed.
